(19) United States
(12) Patent Application Publication
(10) Pub. No.: US 2020/0203794 A1
(43) Pub. Date: Jun. 25, 2020

(54) LOW TEMPERATURE CO-FIRED CERAMIC FILTER

(71) Applicant: AAC Technologies Pte. Ltd., Singapore city (SG)

(72) Inventors: Zenan Liu, Shenzhen (CN); Dawei Zhan, Shenzhen (CN); Yongli Chen, Shenzhen (CN)

(21) Appl. No.: 16/706,864

(22) Filed: Dec. 9, 2019

(30) Foreign Application Priority Data
Dec. 24, 2018 (CN) 201811581885.3

(51) Int. Cl. H01P 1/203; H03H 7/01; H01Q 1/24

(52) U.S. Cl. CPC H01P 1/20345; H03H 2001/0085; H01Q 1/243; H03H 7/0115

(57) ABSTRACT

The present invention provides an LTCC filter, including a shell and a filtering assembly. The filtering assembly includes a first layer, two second layers, and two third layers. The first layer includes a first layer top end and a first layer bottom end. The first layer top end is grounded. The first layer bottom layer forms an open circuit state, and the first layer serves as an inductance L. The second layer includes a second layer top end and a second layer bottom end. The second layer top end forms the open circuit state. The second layer bottom end is grounded. The second layer serves as a grounding capacitor C, and the second layer and the first layer are coupled together to form an LC resonance unit. The third layer is grounded, and serves as a shielding layer of the filter.

### TECHNICAL FIELD

The present invention relates to an antenna, specifically relates to a low temperature co-fired ceramic filter for a field of communication electronic products.

### BACKGROUND

A fifth-generation mobile phone mobile communication standard is further called a fifth-generation mobile communication technology (5G). A future network develops towards a diversified, broadband, comprehensive, and intelligent direction. With popularization of various intelligent terminals, mobile data flows have an explosion type growth. With gradually performing of the 5G network, communication frequency bands of the mobile phone are greatly increased, so that demands of filters are driven to increase.

Due to a fact that a frequency band of Sub 6G belongs to a newly added frequency band in the 5G frequency spectrum, including 3.3 GHz-3.6 GHz and 4.8 GHz-5.0 GH, kinds of filters directed to low temperature co-fired ceramic (LTCC) in a related art are small. Meanwhile, the present filters are complex in structures and large in sizes, and the filters are not comprehensive in coverage of the frequency of Sub 6G, so that using of the filters is limited.

Therefore, it is necessary to provide a novel LTCC filter to solve above problems.

### BRIEF DESCRIPTION OF DRAWINGS

FIG. 1 is a perspective schematic view of an LTCC filter of the present invention.

FIG. 2 is a partial perspective exploded schematic view of the LTCC filter of the present invention.

FIG. 3 is a schematic structural view of a first layer of the LTCC filter of the present invention.

FIG. 4 is a schematic structural view of a second layer of the LTCC filter of the present invention.

FIG. 5 is a schematic structural view of a third layer of the LTCC filter of the present invention.

FIG. 6 is a curve graph of an S parameter of the LTCC filter of the present invention.

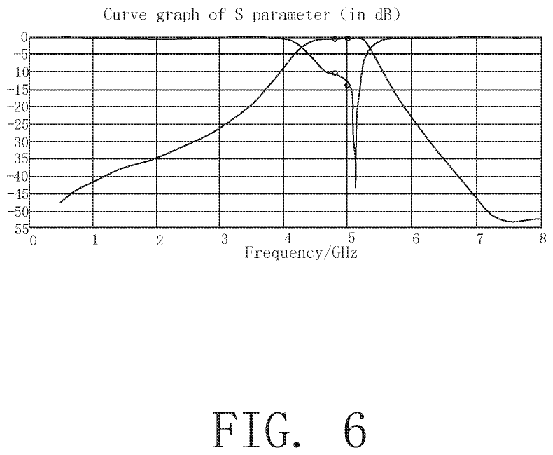

### DETAILED DESCRIPTION OF THE EXEMPLARY EMBODIMENT

The present invention is further described in conjunction with the accompanying drawings and embodiments.

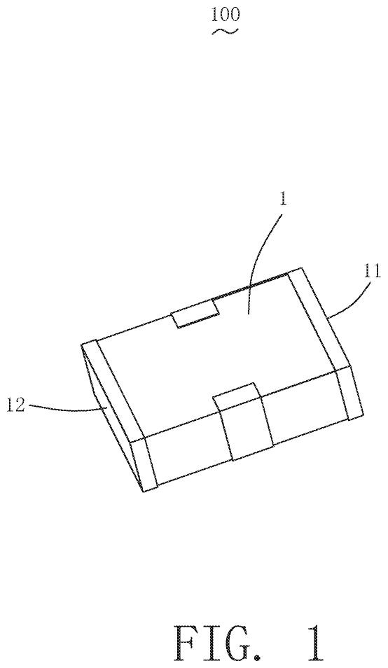

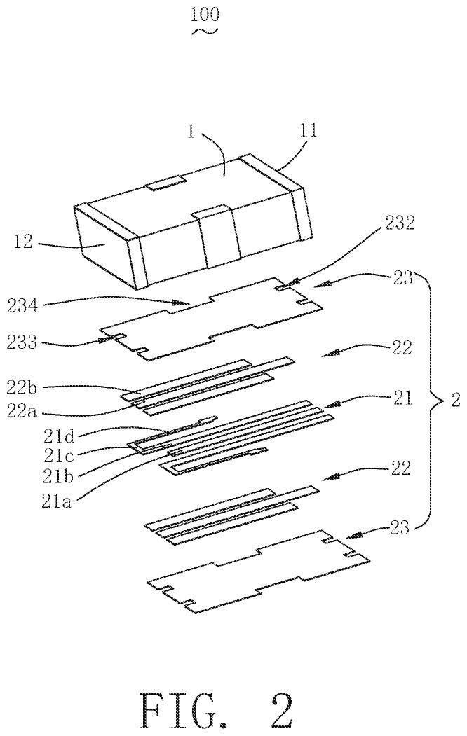

Referring to FIGS. 1-2, the present invention provides an LTCC filter 100, including a shell 1 and a filtering assembly 2 fixedly received in the shell 1.

The shell 1 comprises a top side 11 and a bottom side 12 opposite to the top side 11. In one embodiment, the shell 1 has a rectangular cube shape, such as a cuboid shape. Specifically, the shell 1 in one embodiment has a length, width and height dimension of 3.2 mm*2.4 mm*0.9 mm.

The filtering assembly 2 comprises a first layer 21, two second layers 22, and two third layers 23. Two second layers 22 are respectively overlapped on two opposite sides of the first layer 21, and each of the third layers 23 is respectively overlapped on a side of the two second layer 22 far away from the first layer 21. That is, the filtering assembly 2 has a five-layer structure. The third layer 23, the second layer 22, the first layer 21, the second layer 22, and the third layer 23 are sequentially overlapped from top to bottom. Furthermore, the first layer 21, the second layers 22, and the third layers 23 are perpendicular to the top side 11 and the bottom side 12 of the shell 1.

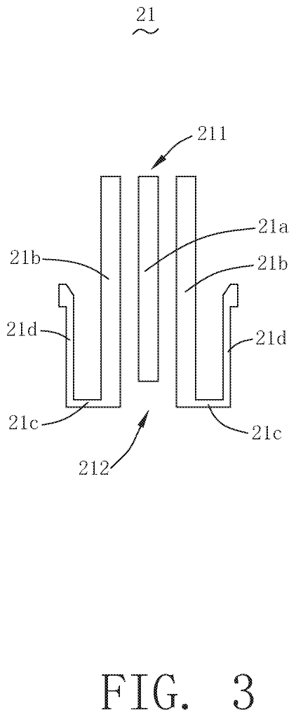

Referring to FIG. 3, the first layer 21 comprises a first layer top end 211 close to the top side 11 and a first layer bottom end 212 close to the bottom side 12. The first layer top end 211 is grounded. The first layer bottom end 212 forms an open circuit state. The first layer 21 is served as an inductance L.

Specifically, the first layer 21 comprises a first conductor 21a, two second conductors 21b, two connecting bodies 21c, and two third conductors 21d. The two second conductors 21b are respectively disposed on two opposite sides of the first conductor 21a, the two connecting bodies 21c extend perpendicularly from two ends of the second conductors 21b close to the bottom side 12 in a direction far away from the first conductor 21a, and the third conductors 21d extend from the connecting bodies 21c in a direction toward the top side 11 and parallel to the first conductor 21a.

The first conductor 21a, the second conductors 21b, and the third conductors 21d are parallel to each other and disposed at intervals. An end of the first conductor 21a close to the top side 11 is flush with ends of the second conductors 21b. An end of the first conductor 21a close to the bottom side 12 is further away from the bottom side 12 than ends of the second conductors 21b close to the bottom side 12.

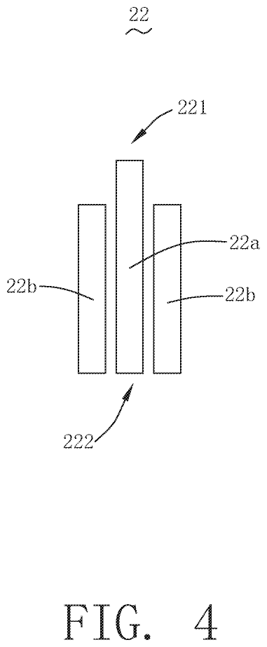

Referring to FIG. 4, the second layer 22 comprises a second layer top end 221 close to the top side 11 and a second layer bottom end 222 close to the bottom side 12. The second layer top end 221 forms the open circuit state, and the second layer bottom end 222 is grounded. The second layer 22 is served as a grounding capacitor C, the second layer 22 and the first layer 21 are coupled together to form an LC resonance unit.

Specifically, the second layer 22 comprises a fourth conductor 22a and two fifth conductors 22b, the two fifth conductors 22b are respectively disposed on two opposite sides of the fourth conductor 22a. The two fifth conductors 22b and the fourth conductor 22a are in parallel and disposed at intervals. An end of the fourth conductor 22a close to the bottom side 12 is flush with ends of the fifth conductors 22b close to the bottom side 12. Ends of the fifth conductors 22b close to the top side 11 are further away from the top side 11 than an end of the fourth conductor 22a close to the top side 11.

In one embodiment, the fourth conductor 22a is overlapped on the first conductor 21a to form coupling, and the two fifth conductors 22b are respectively overlapped on the two second conductors 21b to form coupling.

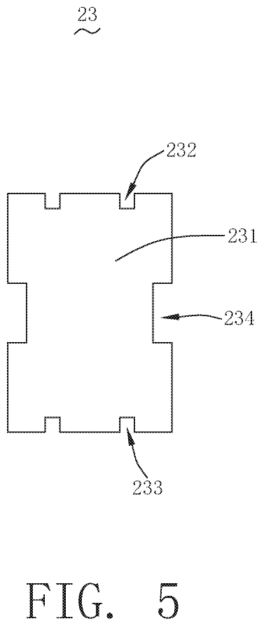

Referring to FIG. 5, the third layer 23 is grounded, and served as a shielding layer of the LTCC filter 100. The third layer 23 is configured for shielding an electronic interference caused by clutter in circuits of the filtering assembly 2 and ensure stability when the LTCC filter 100 works.

Specifically, the third layer 23 comprises a flat plate body 231, two top-end notches 232, two bottom-end notches 233, and two side-end notches 234. The two top-end notches 232 are disposed at intervals at an end of the flat plate body 231 close to the top side 11. The two bottom-end notches 233 are disposed at intervals at an end of the flat plate body 231 close to the bottom side 12, and the two side-end notches 234 are respectively disposed at two side ends of the flat plate body 231.

In one embodiment, orthographic projections of the first layer 21 and the second layers 22 respectively on the third layers 23 are at least partially located in the third layers 23. Ends of the second conductors 21B of the first layer 21 close to the top side 11 are respectively aligned with the two top-end notches 232. The two third conductors 21d of the first layer 21 respectively extend to be aligned with the two side-end notches 234. Two ends of the two fourth conductors 22a of the second layers 22 close to the bottom side 12 are respectively aligned with the two bottom-end notches 233.

The end of the first conductor 21a of the first layer 21 close to the bottom side 12 are further away from the bottom side 12 than the end of the fourth conductor 22a of the second layer 22 close to the bottom side 12. The end of the first conductor 21a close to the top side 11 is closer to the top side 11 than the end of the fourth conductor 22a close to the top side 11.

The ends of the second conductors 21b of the first layer 21 close to the bottom side 12 are flush with ends of the fifth conductors 22b of the second layer close to the bottom side 12, and the ends of the second conductors 21b close to the top side 11 are closer to the top side 11 than the ends of the fifth conductors 22b close to the top side 11.

Compared with the prior art, the LTCC filter sequentially comprises the first layer, the two second layers respectively overlapped on two opposite sides of the first layer, and the two third layers, each of the third layers respectively overlapped on a side of each of the second layers far away from the first layer. The second layer and the first layer are coupled together to form the LC resonance unit. Meanwhile, the structure of the first layer, the second layer, and the third layer is designed so that the LTCC filter covers single frequency band of 4.8-5 GHz or 3.3-3.6 GHz in frequency bands of Sub 6G, which achieves a wide coverage range of the frequency bands. Moreover, the LTCC filter is simple in structure and small in size, so that an applicable range is wider.

Although the present invention is described in reference to the preferred embodiments, it should be understood by those skilled in this filed, the above descriptions are only preferred embodiments of the present invention, and are not intended to limit the present invention, any modification, equivalent replacement and improvement made within the spirit and principle of the present invention should be included within the protection scope of the present invention.

What is claimed is:

1. A low temperature co-fired ceramic filter, comprising:
a shell;
a filtering assembly fixedly received in the shell;
the shell comprising a top side and a bottom side opposite to the top side;
the filtering assembly comprising a first layer, two second layers respectively overlapped on two opposite sides of the first layer, and two third layers; each of the third layers is overlapped on a side of each of the two second layers far away from the first layer; the first layer, the second layers, and the third layers are perpendicular to the bottom side;
the first layer comprising a first layer top end close to the top side and a first layer bottom end close to the bottom side, the first layer top end grounded, the first layer bottom end forming an open circuit state, and the first layer served as an inductance L;
the second layer comprising a second layer top end close to the top side and a second layer bottom end close to the bottom side, the second layer top end forming the open circuit state, the second layer bottom end grounded, the second layer served as a grounding capacitor C, the second layer and the first layer coupled together to form an LC resonance unit;
the third layer grounded, and served as a shielding layer of the LTCC filter.

2. The low temperature co-fired ceramic filter according to claim 1, wherein the first layer comprises a first conductor, two second conductors, two connecting bodies, and two third conductors; wherein,
two second conductors are respectively disposed on two opposite sides of the first conductor;
two connecting bodies extend perpendicularly from two ends of the second conductors close to the bottom side in a direction far away from the first conductor;
the third conductors extend from the connecting bodies in a direction towards the top side and parallel to the first conductor;
the first conductor, the second conductors, and the third conductors are parallel to each other and disposed at intervals;
an end of the first conductor close to the top side is flush with ends of the second conductors; and
an end of the first conductor close to the bottom side is further away from the bottom side than ends of the second conductors close to the bottom side.

3. The low temperature co-fired ceramic filter according to claim 2, wherein the second layer comprises a fourth conductor and two fifth conductors;
two fifth conductors are respectively disposed on two opposite sides of the fourth conductor;
two fifth conductors and the fourth conductor are parallel to each other and disposed at intervals;
an end of the fourth conductor close to the bottom side is flush with ends of the fifth conductors close to the bottom side;
ends of the fifth conductors close to the top side are further away from the top side than an end of the fourth conductors close to the top side;
the fourth conductor is overlapped on the first conductor to form coupling; and
the two fifth conductors are respectively overlapped on the two second conductors to form coupling.

4. The low temperature co-fired ceramic filter according to claim 3, wherein the third layer comprises a flat plate body, two top-end notches, two bottom-end notches, and two side-end notches;
the two top-end notches are disposed at intervals at an end of the flat plate body close to the top side, the two bottom-end notches are disposed at intervals at an end of the flat plate body close to the bottom side, and the two side-end notches are respectively disposed at two side ends of the flat plate body;
orthographic projections of the first layer and the second layer respectively on the third layer are at least partially located in the third layer;
ends of the second conductors of the first layer close to the top side are respectively aligned with the two top-end notches;
two third conductors of the first layer respectively extend to be aligned with the two side-end notches;
two ends of the two fourth conductors of the second layers close to the bottom side are respectively aligned with the two bottom-end notches.

5. The low temperature co-fired ceramic filter according to claim 4, wherein the end of the first conductor of the first layer close to the bottom side is further away from the bottom side than the ends of the fourth conductors of the second layers close to the bottom side;
the end of the first conductor close to the top side is closer to the top side than the ends of the fourth conductors close to the top side.

6. The low temperature co-fired ceramic filter according to claim 4, wherein the ends of the second conductors of the first layer close to the bottom side are flush with ends of the fifth conductors of the second layer close to the bottom side; and,
the ends of the second conductors close to the top side are closer to the top side than the ends of the fifth conductors close to the top side.

7. The low temperature co-fired ceramic filter according to claim 1, wherein the shell has a cuboid shape with a length, width and height dimension of 3.2 mm*2.4 mm*0.9 mm.

8. The low temperature co-fired ceramic filter according to claim 1, wherein the filter works at 4.8-5 GHz.

9. The low temperature co-fired ceramic filter according to claim 1, wherein the filter works at 3.3-3.6 GHz.
